(19) United States
(12) Patent Application Publication
(10) Pub. No.: US 2009/0159928 A1
(43) Pub. Date: Jun. 25, 2009

(54) POWER SEMICONDUCTOR DEVICES

(75) Inventors: Sankara Narayanan Ekkanath Madathil, Leicester (GB); David William Green, Leicestershire (GB)

Correspondence Address: VOLENTINE & WHITT PLLC, ONE FREEDOM SQUARE, 11951 FREEDOM DRIVE SUITE 1260, RESTON, VA, 20190, US

(73) Assignee: ECO SEMICONDUCTORS LTD, Leicester (GB)

(21) Appl. No.: 12/090,122

(22) PCT Filed: Oct. 16, 2006
(86) PCT No.: PCT/GB2006/003833

§ 371 Date: Sep. 12, 2008

(30) Foreign Application Priority Data
Oct. 14, 2005 (GB) 0520909.3

(51) Int. Cl. H01L 29/739

(52) U.S. Cl. 257/141; 257/E29.197

(57) ABSTRACT

A power semiconductor device including source and drain regions located in a lateral arrangement in a first portion of the device, and at least one current providing cell located in a second portion of the device and spaced apart from the first portion at least by a substrate region of a first conductivity type.

This invention relates to power semiconductor devices It is especially concerned with Power Integrated Circuits (Power ICs), with particular, but by no means exclusive, reference to MOS controlled Bipolar devices such as Lateral Insulated Gate Bipolar Transistors (LIGBTs).

The field of power microelectronics generally comprises three different categories of device, differentiated with respect to the location of the high voltage terminal (anode) in relation to the ground and gate terminals The device categories are Discrete Power Devices; Integrated Power Chips (IPCs) and Power ICs. In Discrete Power Devices, the anode is located at the bottom of the device, with the cathode and gate contacts being provided at the top of the device. IPCs are a derivative of Discrete Power Devices in which active control components are integrated within the device. In IPCs, the anode is located at the bottom of the device, and as a result it has generally been difficult to produce IPC structures containing more than one power device. In such IPCs, the control circuits are normally built over an oxide or enclosed within oxide islands, which is expensive. In contrast, Power ICs can be produced having multiple power devices together with associated logic elements. Typically, the power devices used in Power ICs have all three terminals—anode (or drain), gate and cathode (or source)—located at the top of the device. It is also known to provide Power ICs having quasi-vertical power devices in which the anode is brought to the top of the device through, e.g. a metal contact. It is also known to utilise lateral power devices in Power ICs, but a major drawback associated with such devices has been the power ratings of the lateral power devices, this being constrained by the distance between the low voltage and high voltage terminals and the area of the power device. This limitation is due to the need to support voltages laterally, which influences the surface area of the device. Generally, lateral devices in Power ICs operate at relatively low current densities (defined as current per unit area) in comparison to vertical devices, the upper limit for vertical devices being influenced by junction temperature issues and voltage rating.

Different technologies have been used to produce power ICs, and these technologies fall essentially into three categories: Junction Isolation (JI) technology; Silicon-On-Insulator (SOI) technology; and Partial SOI technology. A variant of SOI technology known as Membrane Technology, which is devoid of a substrate, is known.

Each of these technologies has its merits and disadvantages. JI technology is based on using a lightly doped P-type semiconductor substrate as part of a RESURF concept to achieve high breakdown voltage. To date, JI technology has delivered relatively limited performance for a unipolar device such as the Lateral Double Diffused MOSFET (LDMOS) in terms of on-state resistance, current density and switching speed. Whilst it is possible to improve the on-state with multiple RESURF or super-junction techniques, the process control is expensive. The on-state voltage drop can be significantly reduced with the use of bipolar injection, such as in the Lateral Insulator Gate Bipolar Transistor (LIGBT). For example, the chip size associated with LIGBT devices can be reduced by a factor of 5 in comparison to a LDMOS device of the same current rating. However, due to heavy injection of carriers into the substrate, LIGBT devices are not well suited in JI technology for integration with control circuits disposed on the same chip. However JI technology offers one of the lowest cost options.

SOI technology alleviates some of the drawbacks of JI technology, such as the injection into the substrate. However, since the SOI substrate acts as a backside field plate, a thick oxide is required to support high voltages. More recently, it has been shown that removal of the substrate can result in high breakdown voltage—this is the variant of SOI technology known as Membrane Technology. A LIGBT device realised in SOI or membrane technology results in a high on-state forward drop in comparison to a JI-LIGBT.

Partial SOI is a combination of the two technologies, and, whilst it has merits, there are drawbacks pertaining to the processing costs associated with realising a suitable substrate.

The present invention, in at least some of its embodiments, overcomes the above described limitations of MOS bipolar devices employed in power ICs, particularly—although not exclusively—in JI technology. The present invention, in at least some of its embodiments, provides MOS controlled Bipolar devices such as LIGBT devices that can deliver high levels of current without substantially increasing device area. Currents similar to those produced by vertical counterpart devices can be provided. Furthermore, the present invention, in at least some of its embodiments, provides power ICs having multiple high current power devices integrated with multiple logic circuits.

According to a first aspect of the invention there is provided a power semiconductor device including source and drain regions located in a lateral arrangement in a first portion of the device, and at least one current providing cell located in a second portion of the device and spaced apart from the first portion at least by a substrate region of a first conductivity type.

In preferred embodiments, the power semiconductor device is a Lateral Insulated Gate Biopolar Transistor (LIGBT) device, and the source and drain regions in the first portion are present as part of a LIGBT arrangement.

It has been recognised that the surface area occupied by a lateral power device scales directly with the current rating. For example, a 5A device requires typically a surface area that it is five times larger than the surface area for a IA device, thereby making the device bulky. The present invention relates to a device structure that increases the current density per unit area, and thus can increase the current rating for a given chip size. It should be noted that prior art LIGBT devices suffer from high forward voltage drop because their electron injection is not sufficient to enable an increase in the current density. In the present invention, the current providing cell or cells contribute current, thereby increasing current density. The substrate region can act as an “active” region that conducts current while supporting the voltage in the off-state. Moreover, safe-operating area is also improved.

Typically, the first conductivity type is P and the second conductivity type is N. However, it is possible to provide devices in which the first conductivity type is N and the second conductivity type is P. The first portion may be an upper portion of the device and the second portion may be a lower portion of the device or vice versa. Preferably, the current providing cell is controlled by a MOS control structure. Typically, the control structure includes one or more source contacts and one or more gates. Most preferably, the current providing cell is a MOSFET. In another preferred arrangement, the current providing cell is a source region of a LIGBT structure formed on the second portion of the device. Other current providing cells, for example cells providing diode, transistor, thyristor or JFET modes of operation, might be utilised, although MOS control of such current providing cells is preferred. The JFET methodology described in the Applicant's International Publication WO 2006/016160 might be utilised.

At least one cell of the first conductivity type may be provided in the second portion of the device. The cell of the first conductivity type may be provided in order to collect holes, thereby improving the forward bias safe operating area. The cell of the first conductivity type can be in connection with a source contact.

Preferably, the current providing cell is additionally spaced apart from the first portion by at least one region of the second conductivity type disposed beneath the substrate region of the first conductivity type. The region of the second conductivity type may be electrically “floating”. The region of a second conductivity type may be a layer disposed underneath the substrate region. The layer may be continuous or may be discontinuous, and a continuous layer may have channels formed therein. Discontinuities or channels formed in the layer may be filled with material of the first conductivity type, thereby enabling the substrate region to communicate with the current providing cell.

The current providing cell may have a well of the first conductivity type formed thereon. The region of the second conductivity type disposed beneath the substrate region may be formed so that the well of the first conductivity type communicates with the substrate region.

The source region may be in contact with the substrate region. However, in other embodiments the source region is not in contact with the substrate region.

The LIGBT device may be of the type in which: the source region includes a source contact connected to a source well of the first conductivity type and a source sub-region of the second conductivity type located in the source well; the drain region includes a drain contact connected to a drain sub-region of the first conductivity type; the source region is separated from the drain region by a drift region of the second conductivity type; and a gate overlaps a source sub-region, of the source well and the drift region.

The source region may be of trench, planar, reverse channel, multi-channel, or trench planar configuration, or any other appropriate configuration. The cathode region may include cluster cells or thyristor cells.

Gates on the first region of the device can be planar, a trench gate, a trench planar gate or a dummy gate connected to the source separately.

The drain region can be of conventional configuration, anode-short, segmented anode, NPN anode, or anode-gate configuration, or any other suitable drain configuration. The drift region may be undoped, uniformly doped, or the doping concentration may vary along the length, width or depth of the drift region.

Gates on the second portion of the device may be of trench, trench planar, or dummy configuration. Gates disposed in the second portion of the device can be connected to gates disposed on the first portion of the device or these gates can be integrated. Alternatively, gates disposed in the second portion of the device can be operated separately from gates disposed in the first portion of the device.

The device may be realised in bulk technology. Preferably, the device is realised using JI technology, although other technologies, such as Partial SOI, quasi vertical structures on SOI technology, Double Epitaxial Dielectric Isolation technology, Membrane or SOI technology might be utilised.

Typically, the device is formed from silicon, although the use of other materials, such as silicon carbide and gallium nitride, is within the scope of the invention. All types of isolation might be utilised, although a preferred type is described below. The substrate may be of any suitable thickness.

According to a second aspect of the invention there is provided a power integrated circuit including at least one logic circuit and at least one power semiconductor device including source and drain regions located in a lateral arrangement in a first portion of the device, and at least one current providing cell located in a second portion of the device spaced apart from the first portion at least by a substrate region of a first conductivity type. The power semiconductor device can include any of the features discussed above with reference to the first aspect of the invention. Preferably, at least one LIGBT device of the first aspect of the invention is present.

The power integrated circuit may include one or more other power devices such as LDMOS, other bipolar transistors or diode devices. Preferably, the power integrated circuit includes a plurality of logic circuits and a plurality of power semiconductor devices of the first aspect of the invention, most preferably a plurality of LIGBT devices of the first aspect of the invention. Advantageously, the power integrated circuit includes a pair of adjacent power semiconductor devices which are isolated from one another by a trench extending along at least a portion of the boundary between the substrate regions of the power semiconductor devices. This is a preferred way of achieving effective isolation between adjacent power semiconductor devices. A further advantage is that the trench isolation can render the substrate regions more active components of the device, in that a substrate's ability to carry current can be enhanced. Conveniently, the trench can be provided by a suitable etching technique. At least one of the power semiconductor devices may include a deep region of the first conductivity type that contacts the substrate region. A single deep region may be provided on a power semiconductor device, or multiple deep regions may be provided on a power semiconductor device.

A boundary region of the second conductivity type may separate the first portions of the adjacent power semiconductor devices. The boundary region may be selectively formed by implantation or epitaxy.

Advantageously, the trench contacts the boundary region of the second conductivity type and/or the deep region of the first conductivity type. The positioning of the trench may be so as to substantially prevent a current flowing between the power semiconductor devices.

The boundary between the substrate regions of the pair of adjacent power semiconductor devices may comprise the boundary region and the deep region of at least one of the adjacent power devices. Preferably, the deep region or regions extend around at least a portion of the periphery of the boundary region.

Advantageously, both power semiconductor devices in the adjacent pair include a deep region.

Advantageously, the adjacent power semiconductor devices are isolated from one another by more than one trench. Preferably, a pair of trenches are utilised. In a particularly preferred embodiment, a first trench contacts the deep region of one power semiconductor device in the pair, and a second trench extends into the boundary region adjacent the deep region of the other power semiconductor device in the pair. However, it is also possible to utilise embodiments in which the first trench is not aligned with the deep region of the one power semiconductor device.

A deep region of a power semiconductor device may embed a trench which extends from or near to the upper surface of the device. In such embodiments, the trench may be filled from the top with a suitable material, such as an oxide material. The trench may additionally extend through a substrate region.

In some embodiments, one of the power semiconductor devices in the pair is a low-side device and the other power semiconductor device in the pair is a high-side device. It is highly advantageous that the present invention can provide effective isolation between such power semiconductor devices, thereby preventing or at least restricting “cross-talk” between the devices. Preferably, the first trench contacts the deep region of the low-side device and the second trench extends into the boundary region adjacent the deep region of the high-side device in the pair.

Advantageously, a deep region is an isolation well which communicates with an outer layer of the power integrated circuit.

Preferably, the deep region or regions are present in the form of a guard ring. In particularly preferred embodiments, a pair of adjacent power semiconductor devices each have a single guard ring, and the devices are separated by multiple trenches. Typically, the guard ring or rings are grounded.

The trench may be filled with a semiconductor material, preferably polysilicon, which may be doped or undoped. The semiconductor material may be held at a predetermined potential or potential difference. For example, the semiconductor material may be electrically tied to ground potential, or another potential, either positive or negative, or the potential of the semiconductor material may be fixed with respect to the potential of the source contact.

Alternatively, the trench may be filled with an insulating material, preferably an oxide material.

The trench may be connected to at least one gate. The gate may be connected to a potential of any polarity, positive, negative or ground. The gate may be formed from a metal or poly silicon.

The trench may be of a deep trench structure.

It is possible to provide multiple trenches. Multiple trenches may be provided between a pair of adjacent power semiconductor devices. It is strongly preferred that each adjacent pair of LIGBT devices in the power integrated circuits is isolated by at least one trench.

According to a third aspect of the invention, there is provided a power integrated circuit or an integrated power chip including a plurality of logic circuits and individual power devices each having a first portion formed on a substrate region, in which: a pair of adjacent power devices are isolated from one another by a trench extending along at least a portion of the boundary between the substrate regions of the adjacent power devices; at feast one of the adjacent power devices includes a deep region that contacts the substrate region of the device and/or a boundary region of a second conductivity type separates the upper portions of the power devices; and wherein the trench contacts the deep region and/or the boundary region so as to substantially prevent a displacement current flowing between the power devices.

The boundary between the substrate regions of the pair of adjacent power devices may comprise the boundary region and the deep region of at least one of the adjacent power devices. Preferably the deep region or regions extend around at least a portion of the periphery of the boundary region.

Advantageously, both power devices in the adjacent pair include a deep region.

Advantageously, the adjacent power devices are isolated from one another by more than one trench. Preferably, a first trench contacts the deep region of one power device in the pair, and a second trench extends into the boundary region adjacent the deep region of the other power device in the pair. However, it is also possible to utilise embodiments in which the first trench is not aligned with the deep region of the one power device.

A deep region of a power semiconductor device may embed a trench which extends from or near to the upper surface of the device. In such embodiments, the trench may be filled from the top with a suitable material, such as an oxide material. The trench may additionally extend through a substrate region.

Preferably, one of the power devices in the pair is a low-side device and the other power device in the pair is a high-side device. In preferred embodiments, the first trench contacts the deep region of the low-side device and the second trench extends into the boundary region adjacent the deep region of the high-side device in the pair.

A deep region may be an isolation well which communicates with an outer layer of the power integrated circuit or integrated power chip.

Preferably, the deep region or regions are present in the form of a guard ring. In particularly preferred embodiments, a pair of adjacent power semiconductor devices each have a single guard ring, and the devices are separated by multiple trenches. Typically, the guard ring or rings are grounded.

Preferably, the trench or trenches are filled with an insulating material, most preferably an oxide material. Conveniently, the trenches can be formed by etching through the back of a wafer.

Preferably, the power devices are lateral devices, most preferably LIGBT or LDMOS devices. LIGBT devices may be devices of the first aspect of the invention, and the power integrated circuit or integrated power chip may incorporate any of the features of the second aspect of the invention.

Alternatively, the power devices may be vertical devices or quasi-vertical devices.

According to a fourth, related, aspect of the invention, there is provided a power integrated circuit or an integrated power chip including a plurality of logic circuits and individual power devices each having a first portion formed by the substrate region, in which adjacent power devices are isolated from one another by a trench extending along at least a portion of the boundary between the substrate regions of the adjacent power devices, in which at least one of the adjacent power devices includes a deep region that contacts a source region and, preferably, the substrate region of the device and/or a boundary region of a second conductivity type separates the upper portions of the power devices, and wherein the trench contacts the deep region and/or the boundary region so as to substantially prevent a displacement current flowing between the power devices.

Whilst the invention has been described above, it extends to any inventive combination or sub-combination of the features set out above or in the following description or drawings or claims.

Devices in accordance with the invention will now be described with reference to accompanying drawings, in which:—

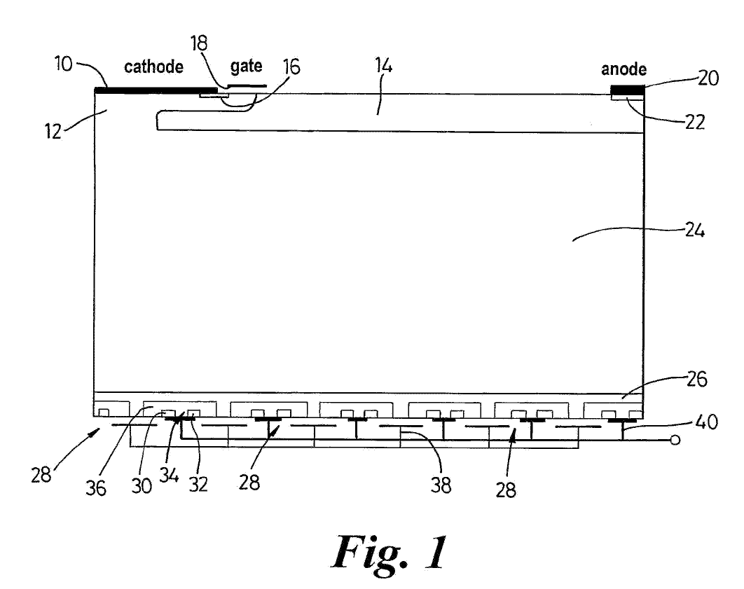

FIG. 1 is a cross-sectional view of a LIGBT device of the invention;

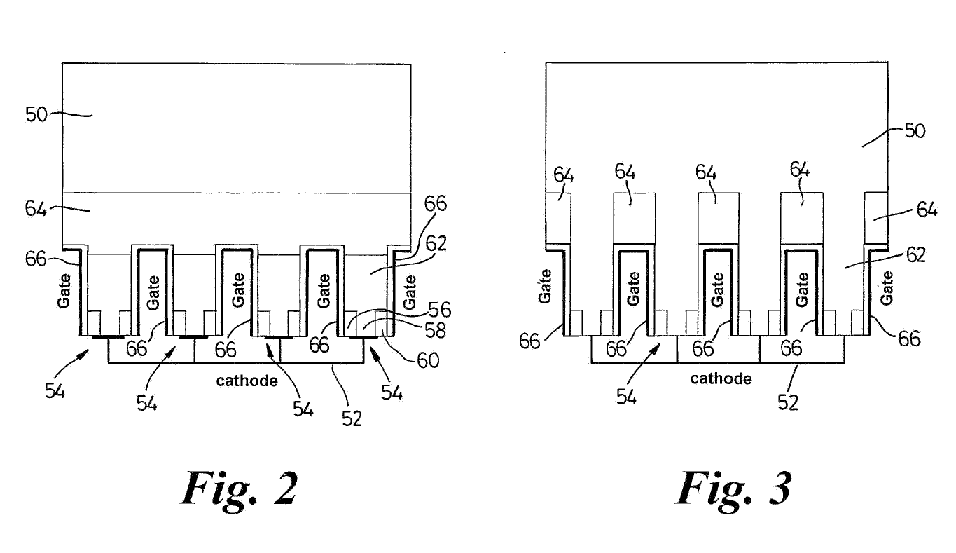

FIG. 2 is a partial cross-sectional view of the lower portion of a second embodiment of a LIGBT device of the invention;

FIG. 3 is a partial cross-sectional view of the lower portion of a third embodiment of a LIGBT device of the invention;

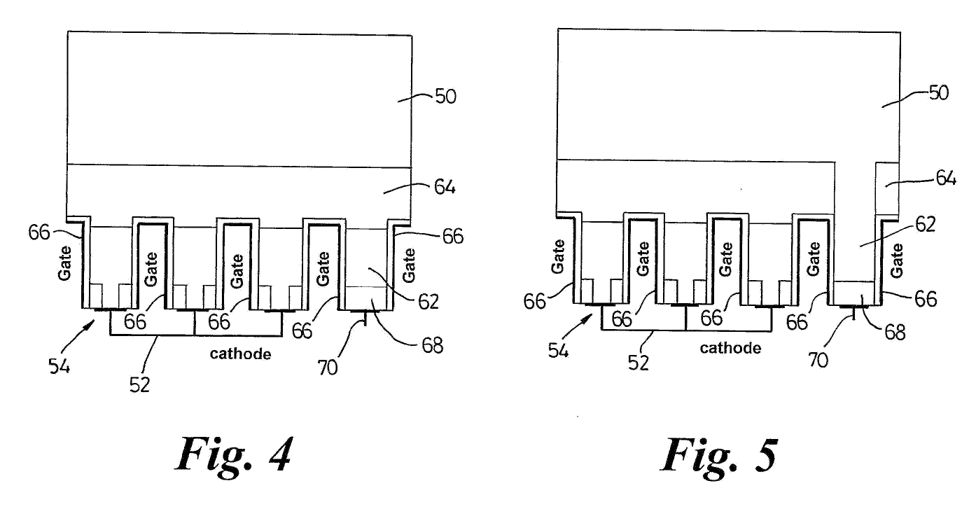

FIG. 4 is a partial cross-sectional view of the lower portion of a fourth embodiment of a LIGBT device of the invention;

FIG. 5 is a partial cross-sectional view of the lower portion of a fifth embodiment of a LIGBT device of the invention;

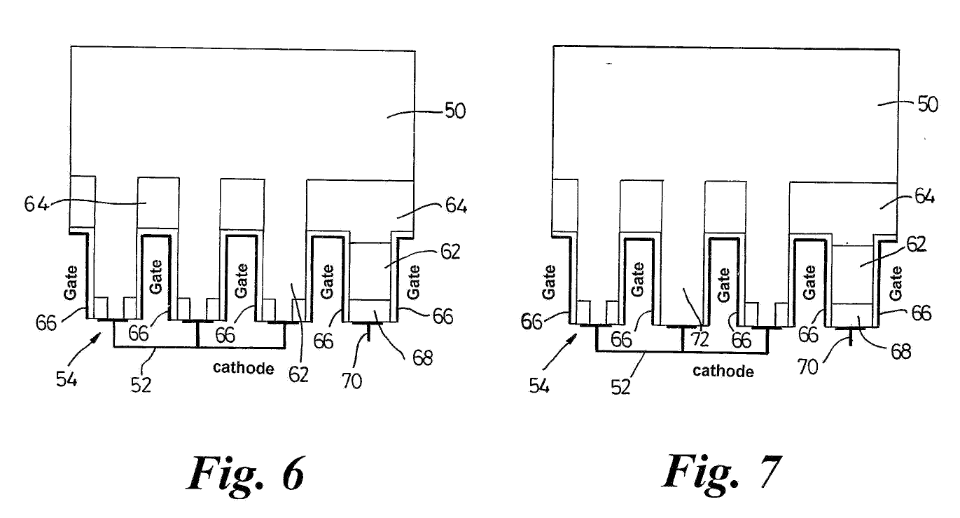

FIG. 6 is a partial cross-sectional view of the lower portion of a sixth embodiment of a LIGBT device of the invention;

FIG. 7 is a partial cross-sectional view of the lower portion of a seventh embodiment of a LIGBT device of the invention;

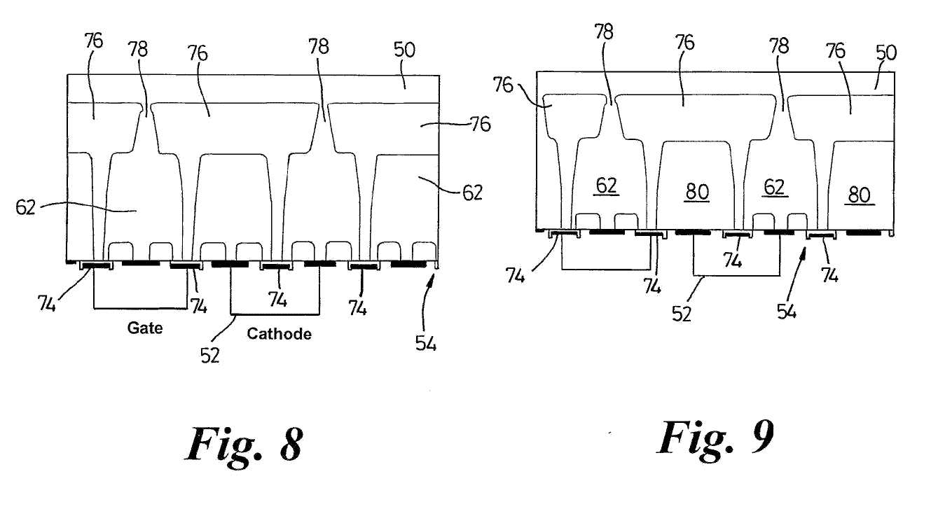

FIG. 8 is a partial cross-sectional view of the lower portion of an eighth embodiment of a LIGBT device of the invention;

FIG. 9 is a partial cross-sectional view of the lower portion of a ninth embodiment of a LIGBT device of the invention;

FIG. 10 is a partial cross-sectional view of the lower portion of a tenth embodiment of a LIGBT device of the invention;

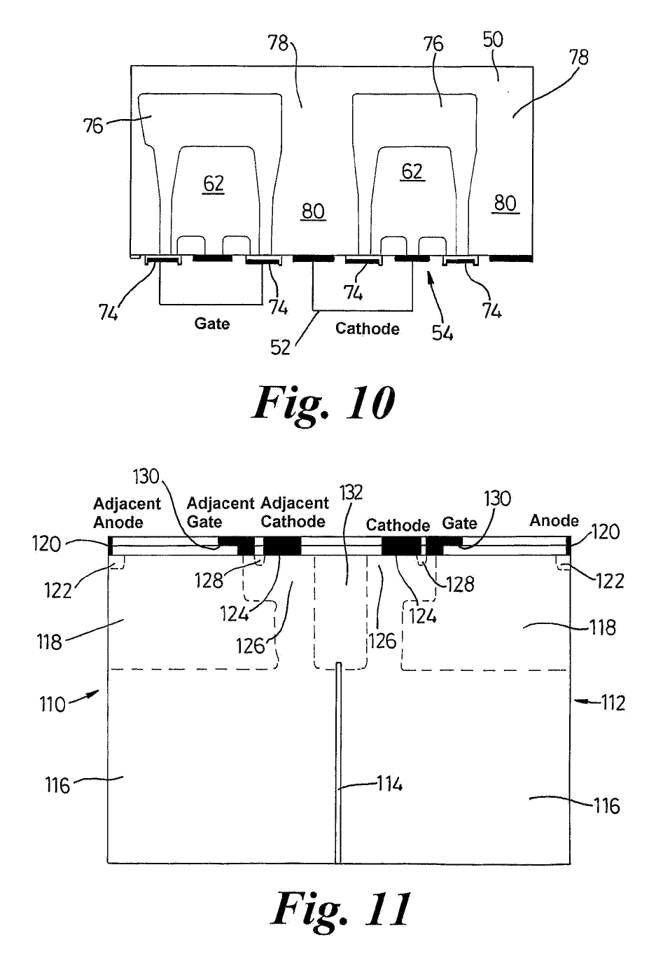

FIG. 11 is a cross-sectional view of a power integrated circuit having two trench isolated LIGBT devices;

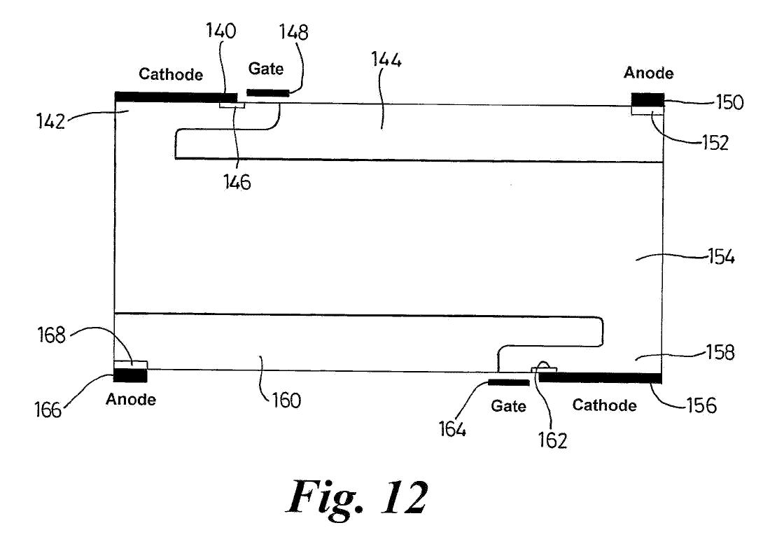

FIG. 12 is a cross-sectional view of an eleventh embodiment of a LIGBT device of the invention;

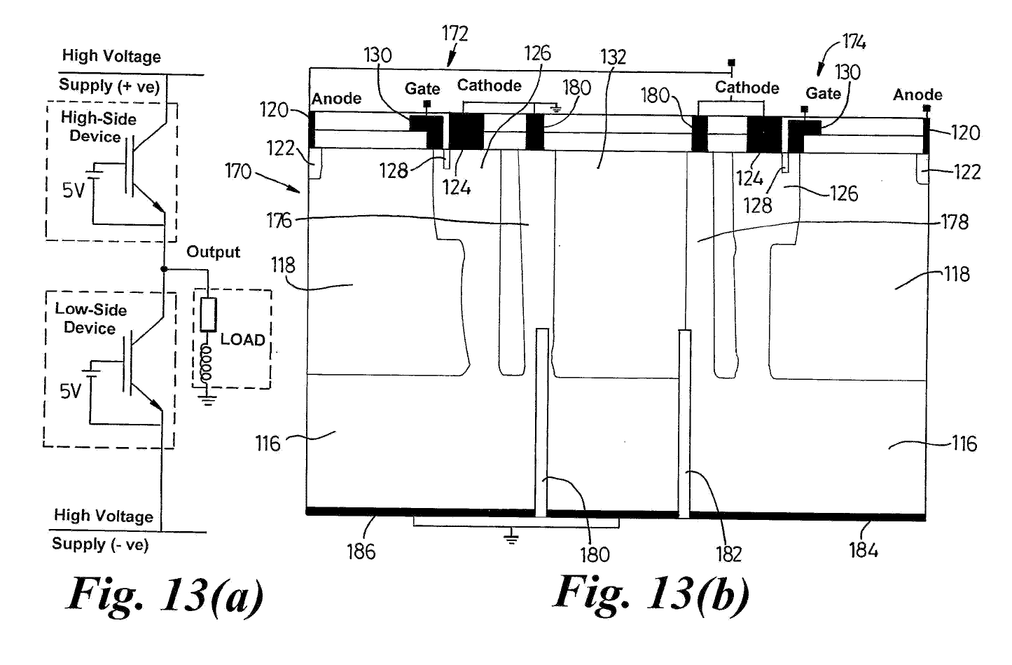

FIG. 13 shows (a) an equivalent circuit and (b) a cross-sectional view of a second embodiment of a power integrated circuit; and

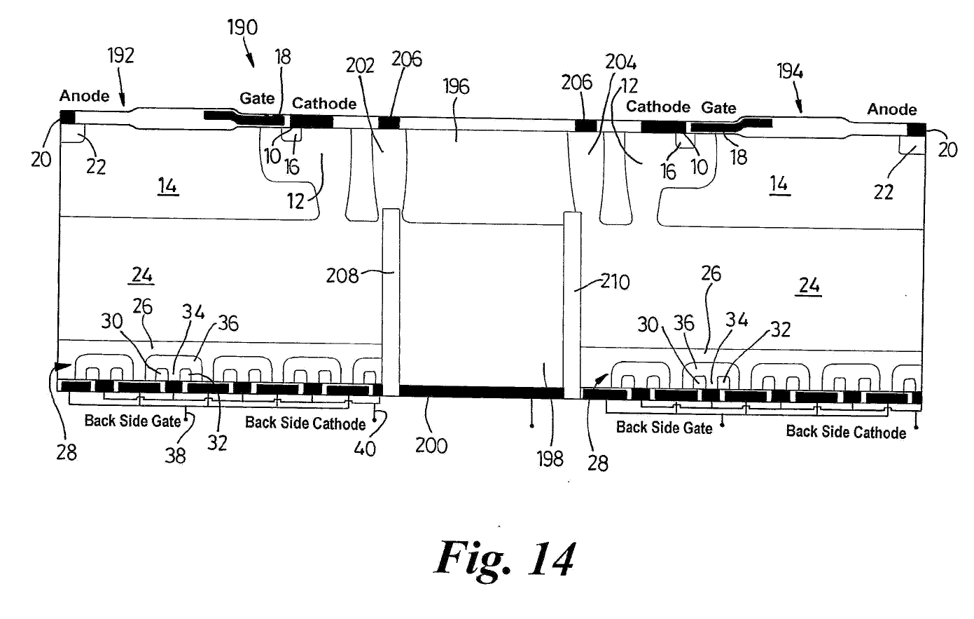

FIG. 14 is a cross-sectional view of a third embodiment of a power integrated circuit.

FIG. 1 shows a first embodiment of a LIGBT device comprising a source contact 10 (the cathode in this example), a P+ well 12 to which the source contact 10 is made and a N− drift region 14. Located in the P+ well 12 is a N+ source sub-region 16. A gate 18 is disposed over a portion of the P+ well 12 and overlaps with the N+ source sub-region 16 and the N− drift region 14. The LIGBT device further comprises a drain contact 20 (the anode in this example) which is in contact with a P+drain region 22 located in the N− drift region 14. The features of the LIGBT device described above constitute the upper portion of the device. The drift region 14 and P+ well 12 are formed on a P substrate 24, and located underneath the P substrate 24 is a N region 26 in which are integrated a plurality of MOSFET cells 28. The N region 26 can be of low to high concentration, and can be formed by implantation or epitaxy. The concentration of the N region 26 may be such that self-clamping occurs in the lower portion of the device (the self-clamping phenomenon is described in international Publication WOO1/18876 and the Applicant's co-pending International Application PCT/GB2005/003146). The N region 26 is not in direct contact to any terminal, and is electrically “floating”.

The MOSFET cells 28 comprise a first N+ cell 30, a second N+ cell 32, and a P+ cell 34 separating the first 30 and second 32 N+ cells. The cells 30, 32, 34 are located in a P+ well 36. Also provided is a gate structure 38 and a cathode structure 40. The cathode structure is such that a cathode is formed on each MOSFET cell 28 overlapping the first N+ cell 30, P+ cell 34, and second N+ cells 32. The gate structure 38 overlays an N+ cell 30 or 32, a P+ cell 36 and N region 26. The gate structure 38 can be of any suitable form, such as a doped polysilicon layer formed over an insulator such as silicon dioxide.

The operation of the device will now be described:—

Under the forward blocking stage, the P substrate layer 24 supports the depletion region, as in the case of a conventional device. In the case of thin substrates, the depletion layer may reach the floating N region 26 at the bottom of the substrate 24 at a certain anode voltage. Depending upon the doping of the N region 26 this may result in self-clamping as in the case of devices described in International Publication WOO1/18876. In other circumstances, the depletion region does not contact the N region 26, even if the substrate is thin, in which instance the blocking behaviour is similar to a conventional device.

On-state: Different cases can be described, depending on whether the P+ well is connected to the substrate 24 and on the thickness of the drift region.

(I) When the Upper Cathode is Connected to the Substrate:

Prior to on-state conduction, the N− drift region 14/P substrate region 24 is reverse-biased. When the voltage of the gate 18 is above the threshold voltage of the MOS region, the N− drift region 14 is brought to ground potential. When the anode potential is above the bipolar on-state voltage, holes are injected from the anode, while electrons are supplied from the cathode contact 10. However, when the holes are injected, the vertical transistor formed by the P+ anode 22, N− drift region 14 and P substrate 24 reaches saturation at a very low anode voltages and the junction is no longer reverse biased. The electric field across the junction disappears and carriers move deep into the substrate 24. Without wishing to be bound by any particular theory, it is believed that this is due to the Kirk effect, and is defined as current induced base widening. Under this condition, the potential difference across the N− drift region 14/P substrate 24 is nearly zero and this region will follow the anode potential as the carriers go as deep as possible into the substrate 24 under normal operating conditions. During the on-state the depth to which carriers move will depend upon the current density, substrate doping and the drift length.

The bottom gate structure 38 is biased with respect to the cathode structure 40. When its gate voltage exceeds the threshold voltage, the N region 26 is brought to ground potential. Due to the base widening effect, the potential of the substrate region 24 increases with the anode voltage. When the difference in the potential between the N region 26/P substrate 24 exceeds the bipolar on-set voltage, the electrons from the lower cathode structure 40 flow towards the anode and holes from the anode flow to the cathode structure 40 as well as to the upper cathode contact 10. The additional channels provide a significant amount of electrons to reduce the on-state voltage drop.

(II) When the Upper Cathode is not Connected to the Substrate and the N Region 14 is Sufficiently Thick

Prior to on-state conduction, the N− drift region 14/P− substrate region 24 is reverse-biased. When the gate 18 of the upper cell is above the threshold voltage of the MOS region, the N− drift region 14 is brought to ground potential. When the anode potential is above the bipolar on-state voltage, holes are injected from the anode, while electrons are supplied from the cathode contract. The floating substrate follows the potential of the anode.

The gate structure 38 is biased with respect to the cathode structure 40. When its gate voltage exceeds the threshold voltage, the N region 26 is brought to ground potential. When the difference in the potential between the N region 16/P substrate 24 exceeds 0.7 V, either through capacitive coupling (occurring when the P substrate is floating so that the P substrate follows the potential of the anode) or the current induced base widening effect, the electrons from the lower cathode structure 40 flow towards the anode and holes from the anode flow to the cathode structure 40 as well as the upper cathode contact 10. The additional channels provide a significant amount of electrons to reduce the on-state voltage drop.

The thickness of the substrate has an influence on the device behaviour. When the substrate is very thick, the bottom channels will contribute only when the potential difference across the substrate region near the bottom N layer increases above its built-in potential.

When the top gate is off, the device will not turn-on, irrespective of whether or not the bottom gates are ‘ON’.

(III) When the Upper Cathode is not Connected to the Substrate and the N Region is not Sufficiently Thick.

Prior to on-state conduction, the N− drift region 14/P substrate region 24 is reverse-biased. When the gate voltage of the upper cell is above the threshold voltage of the MOS region, the N− drift region is brought to ground potential. When the anode potential is above the bipolar on-state voltage, holes are injected from the anode, while electrons are supplied from the cathode contact. The floating substrate follows the potential of the anode. However, when the holes are injected, the vertical transistor formed by the P+ anode 22, N− drift region 14 and P substrate 24 reaches saturation at very low anode voltages and the junction is no longer reverse biased. The electric field across the junction disappears and carriers move deep into the substrate. Without wishing to be bound by any particular theory, it is believed that this is due to the Kirk effect and, as discussed above, is defined as current induced base widening. Under this condition, the potential drop across the N drift region 14/P substrate 24 is nearly zero and the carriers go deep into the substrate under normal operating conditions. During the on-state the depth to which carriers move will depend upon the current density.

The gate structure 38 is biased with respect to the cathode structure 40. When the voltage of the gate 18 exceeds the threshold voltage, the N region 26 is brought to the ground potential. When the difference in the potential between the N region 26/P substrate 24 exceeds 0.7 V, the electrons from the bottom contacts flow towards the anode and holes from the anode flow to the lower cathode structure 40 as well as the upper cathode contact 10. The additional channels provide a significant amount of electrons to reduce the on-state voltage drop.

As per the RESURF principle, the concentration, thickness and length of the N drift region 14 is optimised to obtain the desired voltage. The thickness of the P substrate has an influence on the device behaviour. When the P substrate is very thick, the bottom channels will contribute only when the P substrate region near the bottom N layer increases in potential to above 0.7V. When the top gate is off, the device will not turn-on independent of the potential of the bottom gate. The thickness, length and concentration of the P substrate are also optimised according to the desired device performance.

Turn-Off: During the turn-off, the turn-off of the upper cathode contact 10 will result in carriers moving towards the P substrate, which will be extracted by the lower cathode structure 40. It is possible to turn off the gate 18 and gate structure 38 simultaneously, which will result in device turn-off.

At very high current densities, turning off of the lower channels first before the upper channel is shut off might cause reliability problems due to current crowding at the top cathode and should be prevented.

Benefits associated with the present invention include the following. The lower gates/cathodes do not experience the classical JFET effect; they do not support any large voltage under normal operating conditions and therefore the channel density can be extremely high. The lower gates and the cathodes can be advantageously operated independently to the upper gate and cathode, although coupled or even integrated operation is possible. In vertical devices, the P substrate does not exist; in the present invention, the P substrate supports the voltage. It is possible for the lower region of the device to act as a high side cathode. With appropriate grading of substrate concentration, it is possible to achieve high breakdown voltage, if necessary, while reducing the substrate thickness. The lower gate and cathode regions can enable carriers to be diverted away from the upper cathode region, thereby improving the Forward Bias Safe Operating Area. Additionally, devices of the invention can operate at high current densities. The invention applies to both low and high side switches, and the high side cathode and gate can exist in the upper or lower portion of the device. Structures of the invention can be realised through double side processing or through wafer bonding.

FIGS. 2 to 10 depict numerous variations to the configuration of the current providing cells and the area of the device near to the current providing cells. In all of the FIGS. 2 to 10, a P substrate 50 and cathode structure 52 is present. Also present in these Figures are MOSFET cells 54 comprising a first N+ cell 56, a second N+ cell 58, a P+ cell 60 separating the first and second N+ cells 56, 58 and a P well 62 located over the first and second N+ cells 56, 58 and P+ cell 60. In FIG. 2, a N layer 64 separates the MOSFET cells 54 from the P substrate 50. Trench gates 66 are provided. FIG. 3, trench gates 66 are also provided, but the N layer 64 is discontinuous in nature, allowing the P substrate 50 to communicate with the P well 62. In FIG. 4 a continuous N layer 64 is provided together with trench gate 66. Also provided is a N+ cell 68 with a P well 62 located thereon. A contact 70 to the N+ cell 68 may be provided, but is not connected to any potential so that the N+ cells 68 is electrically floating. FIG. 5 shows a variant of the embodiment shown in FIG. 4, in which the N layer 64 is discontinuous so as to allow the P substrate 50 to communicate with the P well 62 disposed over the N+ cell 68. FIG. 6 shows a further variant of the embodiment shown in FIG. 4, in which the N layer 64 is discontinuous so as to allow the P substrate 50 to communicate with the P wells 62 of the MOSFET cells 54. FIG. 7 shows a variant on the embodiment of FIG. 6 in which a P well 72 communicates with P substrate 50 and extends to the base of the device where contact is made with the cathode structure 52.

FIGS. 8 to 10 depict embodiments in which planar gates 74 are utilised, and a plurality of N wells 76 are disposed beneath the P substrate 50. The N wells 76 have one or more portions that each communicate with a planar gate 74 on the bottom portion of the device. In FIG. 8, a plurality of MOSFET cells 54 are provided. The MOSFET cells 54 alternate between configurations in which the P well 62 of a MOSFET cell communicates with the P substrate 50 via channels 78 formed between adjacent N wells 76, and cells in which the associated P well 62 does not communicate with the P substrate 50 due to the presence of an N well 76. FIG. 9 shows a variant on the embodiment of FIG. 8 in which the MOSFET cells 54 communicate with the P substrate 50 via the channels 78. Also provided are P+ cells 80 which are in contact with cathode structure 52, and are each located underneath an N well 76 so that the P+ cells 80 do not communicate with the P substrate 50. FIG. 10 shows a variant on the embodiment shown in FIG. 9 in which the MOSFET cells 54 do not communicate with the P substrate 50 by virtue of being located within N wells 76, whereas the P cells 80 are in communication with the P substrate 50 via channels 78. The skilled reader will appreciate that many further variations on the structures shown in FIGS. 2 to 10 are possible. For example, trench gates may be replaced with planar gates or vice versa. It should be noted that the current providing cells do not have to be located directly beneath the anode, cathode or the drift region.

FIG. 12 shows a further embodiment of a LIGBT device having an upper region that is very similar to the upper region of the device shown in FIG. 1, comprising a cathode contact 140, a P+ well 142 to which the cathode contact 140 is made and a N− drift region 144. Located in the P+ well 142 is N+cathode sub-region 146. A gate 148 is disposed over a portion of the P+ well 142 and overlaps with the N+ cathode sub-region 146 and the N− drift region 144. The LIGBT device further comprises an anode contact 150 which is in contact with a P+ anode region 152 located in the N− drift region 144. In common with the device shown in FIG. 1, the N− drift region 144 and P+ well 142 are formed on a P substrate 154. In the embodiment shown in FIG. 12, the lower portion of the device comprises a further LIGBT structure. The further LIGBT structure formed in the lower portion of the device comprises a lower cathode contact 156, a P+ well 158 to which the cathode contact 156 is made and a N− drift region 160. Located in the lower P+ well 158 is a lower N+cathode sub-region 162. A lower gate 164 is disposed over a portion of the lower P+ well 158 and overlaps with the lower N+ cathode sub-region 162 and the lower N− drift region 160. The lower LIGBT structure further comprises a lower anode contact 166 which is in contact with a lower P+ anode region 168 located in the lower N− drift region 160. The lower N− drift region 160 is formed below and is contact with the P substrate 154. The lower P+ well 158 is also in contact with the P substrate 154, although it is possible to provide embodiments in which such contact is not made. In FIG. 12, the lower cathode is generally aligned in register with the upper anode and vice versa. Embodiments in which upper and lower cathodes are generally aligned in register, and upper and lower anodes are generally aligned in register are also possible. In the embodiment shown in FIG. 12, the cathode of the lower LIGBT structure acts as a current providing cell, and the P substrate 154 provides a common link for current provision between the upper and lower portions of the device. The upper and lower LIGBT structures can operate simultaneously or alternatively.

LIGBTs have been used in Power ICs wherein a plurality of LIGBTs and/or LDMOSs and associated control circuitry are integrated on the same chip. It is important to achieve effective electrical isolation between power devices in Power ICs of this type. The present invention provides effective electrical isolation by utilising a trench in the substrate to separate adjacent Power devices. FIG. 11 shows an example in which adjacent power devices 110, 112 are separated by a trench 114. The trench separates the P substrates 116 of the power devices 110, 112. Each power device 110, 112 further comprises a N− drift region 118 disposed over the P substrate 116, an anode contact 120 contacting a P+ anode region 122 formed in the N− drift region 118. Spaced apart from the anode 120 by the N− drift region 118 is a cathode contact 124 connected to a P+ cathode well 126 and a N+ cathode sub-region 128. The P+ cathode well 126 comprises a deep region which is in contact with the P substrate 116. A gate 130 overlaps with the cathode sub-region 128, cathode P+ well 126 and N− drift region 118. The cathode of the adjacent power devices 110, 112 are “back-to-back”, and are separated from one another by a N− sandwich region 132. The trench 114 contacts and extends slightly into the sandwich region 132 and thus provides effective electrical isolation of the devices 110, 112, preventing currents flowing between the power devices.

The trench 114 can be produced conveniently using etching technologies, and the sandwich region 132 can be selectively formed by implantation or epitaxy. The trench can be left unfilled, or might be filled (or partially filled) with a material which might be an insulator or a semiconductor material. A preferred semiconductor material is polysilicon, which might be doped or undoped. Multiple trenches can be formed if required. In other embodiments, one or more deep P+ regions are provided on a power device which are in contact with the P substrate. Effective isolation can also be provided by arranging for the trench to terminate in a deep P+ region.

FIG. 13(b) depicts a further example of a power integrated circuit, shown generally at 170, comprising an integrated low-side LIGBT device 172 and high-side LIGBT device 174. FIG. 13(a) shows the equivalent circuit diagram. The embodiment of FIG. 13 shares many features with the device shown in FIG. 11, and identical numerals were used to denote such shared features. In the device 170 shown in FIG. 13(b), the low-side LIGBT device 172 has a grounded P+ isolation well 176 in the form of a guard ring which encloses the low-side LIGBT device 172 and is in contact with the sandwich region 132. Similarly, the high-side LIGBT device 174 has a grounded P+ isolation well 178 in the form of a guard ring which encloses the high-side device 178. Each P+ isolation well 176, 178 is in contact with a metalised contact 180 on the upper surface of the Power IC device 170 and the P substrates 116 of the device. The Power IC 170 further comprises a pair of trenches 180, 182 which extend from the lower side of the device through the P substrate 116. The trench 180 is aligned with, and extends into, the P+ isolation well 176 of the low-side LIGBT device 172. In contrast, the trench 182 is not aligned with the P+ isolation well 178 of the high-side LIGBT device 174, but rather extends into the sandwich region 132 adjacent the P+ isolation well 178 of the high-side LIGBT device 174. This ensures that the high-side substrate 184 is electrically floating, and not shorted to the low-side substrate 186. It has been found that this configuration enables the compact integration of multiple high voltage devices with excellent isolation of adjacent devices. The trenches are preferably filled with oxide and can be produced by etching from the lower side of the power IC device. The isolation wells can be produced by implanting from the upper side of the power IC device.

FIG. 14 depicts a further embodiment of a power IC, shown generally at 190, comprising a low-side LIGBT device 192 and a high-side LIGBT device 194. The LIGBT devices 192, 194 are adjacent and isolated. Both LIGBT devices 192, 194 share many of the features shown in the embodiment of FIG. 1, and identical numerals are used to depict such shared features. The LIGBT devices 192, 194 are separated by a N− sandwich region 196 which resides upon a P− sandwich region substrate 198 and a sandwich region substrate 200. In common with the embodiment shown in FIG. 13, the low-side LIGBT device 192 has a P+ isolation well 202 in the form of a guard ring which encloses the device 192, and the high-side LIGBT device 194 has a P+ isolation well 204 in the form of a guard ring which encloses the high-side device 194. The P+ isolation wells 202, 204 are separated by and are in contact with the N− sandwich region 196, and extend towards the upper surface of the Power IC device 190 where contact is made with electrical contacts 206. The Power IC device 190 further comprises a pair of trenches 208, 210 which extend through the P− sandwich substrate 198 from the lower surface of the power IC device 190. In common with the embodiments shown in FIG. 13, the trench 208 is aligned with and extends into the P+ isolation well 202 of the low-side LIGBT device 192, whereas the trench 210 is not aligned with the P+ isolation well 204 of the high-side LIGBT device 194, but rather extends into the N− sandwich region 196 adjacent the P+ isolation well 204. This ensures that the high-side substrate is not shorted to the low-side substrate. Preferably, the trenches 208, 210 are filled with insulating material such as oxide. The devices shown in FIGS. 13 and 14 can be used in a half bridge circuit. Conveniently, these devices can be realised using JI technology. This is advantageous, because, in the prior art, the common substrate between adjacent devices in JI based power IC's make it difficult to realise a high-side configuration owing to punch through into the substrate.

The trench isolation can be applied to isolate lateral devices other than LIGBTs, such as LDMOS devices or other lateral devices. Additionally, it is possible to isolate vertical devices or quasi-vertical devices using the trench isolation provided by the invention. Integrated power chips having a plurality of power devices might be produced in this way. Devices of the invention can be realised using semiconductors other than silicon, such as silicon carbide or gallium nitride. It is possible to utilise a combination of semiconductor materials, e.g., for one power device to be formed from a first semiconductor material and a second power device to be formed from a second semiconductor material.

1-45. (canceled)

46. A power semiconductor device including source and drain regions located in a lateral arrangement in a first portion of the device, and at least one current providing cell located in a second portion of the device and spaced apart from the first portion at least by a substrate region of a first conductivity type.

47. A power semiconductor device according to claim 46 in which the source and drain regions in the first portion are present as part of a lateral insulated gate bipolar transistor (LIGBT) arrangement.

48. A power semiconductor device according to claim 46 in which the current providing cell is controlled by a MOS control structure.

49. A power semiconductor device according to claim 48 in which the current providing cell is a MOSFET.

50. A power semiconductor device according to claim 48 in which the current providing cell is a source region of a LIGBT structure formed on the second portion of the device.

51. A power semiconductor device according to claim 46 further including at least one cell of the first conductivity type located in the second portion of the device.

52. A power semiconductor device according to claim 46 in which the current providing cell is additionally spaced apart from the first portion by at least one region of a second conductivity type disposed beneath the substrate region.

53. A power semiconductor device according to claim 47 in which:
the source region includes a source contact connected to a source well of the first conductivity type and a source sub-region of the second conductivity type located in the source well;
the drain region includes a drain contact connected to a drain sub-region of the first conductivity type;
the source region is separated from the drain region by a drift region of the second conductivity type; and
a gate overlaps the source sub-region, the source well and the drift region.

54. A power integrated circuit including at least one logic circuit and at least one power semiconductor device including source and drain regions located in a lateral arrangement in a first portion of the device, and at least one current providing cell located in a second portion of the device and spaced apart from the first portion at least by a substrate region of a first conductivity type.

55. A power integrated circuit according to claim 54 in which at least one of the power semiconductor devices is a LIGBT device.

56. A power integrated circuit according to claim 54 including a plurality of logic circuits and a plurality of power semiconductor devices as described in claim 54.

57. A power integrated circuit according to claim 56 in which a pair of adjacent power semiconductor devices are isolated from one another by a trench extending along at least a portion of the boundary between the substrate regions of the power semiconductor devices.

58. A power integrated circuit according to claim 57 in which at least one of the power semiconductor devices includes a deep region of the first conductivity type that contacts the substrate region.

59. A power integrated circuit according to claim 57 in which a boundary region of the second conductivity type separates the first portions of the adjacent power semiconductor devices.

60. A power integrated circuit according to claim 57 in which the trench contacts the boundary region of the second conductivity type and/or a deep region of the first conductivity type so as to substantially prevent a current flowing between the power semiconductor devices.

61. A power integrated circuit according to claim 60 in which the boundary between the substrate regions of the pair of adjacent power semiconductor devices comprises the boundary region and the deep region of at least one of the adjacent power semiconductor devices.

62. A power integrated circuit according to claim 61 in which the deep region or regions extend around at least a portion of the periphery of the boundary region.

63. A power integrated circuit according to claim 58 in which both power semiconductor devices in the adjacent pair include a deep region.

64. A power integrated circuit according to claim 57 in which a first trench contacts the deep region of one power semiconductor device in a pair, and a second trench extends into the boundary region adjacent the deep region of the other power semiconductor device in the pair, the trenches isolating the adjacent power semiconductor devices from one another.

65. A power integrated circuit according to claim 56 in which one of the powered semiconductor devices in the pair is a low-side device and the other power semiconductor device in the pair is a high-sided device.

66. A power integrated circuit according to claim 64 in which one of the powered semiconductor devices in the pair is a low-side device and the other power semiconductor device in the pair is a high-side device, and wherein the first trench contacts the deep region of the low-side device and the second trench extends into the boundary region adjacent the deep region of the high-side device in the pair.

67. A power integrated circuit according to claim 58 in which a deep region is an isolation well which communicates with an outer layer of the power integrated circuit.

68. A power integrated circuit according to claim 58 in which the deep region or regions are present in the form of a guard ring.

69. A power integrated circuit according to claim 57 in which the trench is connected to at least one gate.

70. A power integrated circuit or an integrated power chip including a plurality of logic circuits and individual power devices each having a first portion formed on a substrate region, in which:
a pair of adjacent power devices are isolated from one another by a trench extending along at least a portion of the boundary between the substrate regions of the adjacent power devices;
at least one of the adjacent power devices includes a deep region that contacts the substrate region of the device and/or a boundary region of a second conductivity type separates the first portions of the power devices; and
wherein the trench contacts the deep region and/or boundary region so as to substantially prevent a current flowing between the power devices.

71. A power integrated circuit or integrated power chip according to claim 70 in which the boundary between the substrate regions of the pair of adjacent power devices comprises the boundary region and the deep region of at least one of the adjacent power devices.

72. A power integrated circuit or integrated power chip according to claim 71 in which the deep region or regions extend around at least a portion of the periphery of the boundary region.

73. A power integrated circuit or integrated power chip according to the claim 70 in which both power devices in the adjacent pair include a deep region.

74. A power integrated circuit or integrated power chip according to claim 73 in which a first trench contacts the deep region of one power device in the pair, and a second trench extends into the boundary region adjacent the deep region of the other power device in the pair, the trenches isolating the adjacent power devices from one another.

75. A power integrated circuit or integrated power chip according to claim 71 in which one of the power devices in the pair is a low-side device and the other power device in the pair is a high-side device.

76. A power integrated circuit or integrated power chip according to claim 74 in which one of the power devices in the pair is a low-side device and the other power device in the pair is a high-side device, and wherein the first trench contacts the deep region of the low-side device and the second trench extends into the boundary region adjacent the deep region of the high-side device in the pair.

77. A power integrated circuit or integrated power chip according to claim 70 in which a deep region is an isolation well which communicates with an outer layer of the power integrated circuit or integrated power chip.

78. A power integrated circuit or integrated power chip according to claim 70 in which the deep region or regions are present in the form of a guard ring.

79. A power integrated circuit according to claim 70 in which the power devices are lateral devices, preferably LIGBT or LDMOS devices.
